(19) United States
(12) Patent Application Publication
(10) Pub. No.: US 2025/0251421 A1
(43) Pub. Date: Aug. 7, 2025

(54) ELASTIC CONTACTOR WITH ENHANCED BONDING

(71) Applicant: NANOSYS CO., LTD., Cheongju-si (KR)

(72) Inventor: WOO-HEE NAM, Daejeon (KR)

(21) Appl. No.: 19/037,113

(22) Filed: Jan. 25, 2025

(30) Foreign Application Priority Data
Feb. 2, 2024 (KR) 10-2024-0016403

(51) Int. Cl. G01R 1/067; G01R 31/28

(52) U.S. Cl. CPC G01R 1/06716; G01R 1/06733; G01R 1/06755; G01R 31/2886

(57) ABSTRACT

The present disclosure relates to a contactor that comes into contact with a test inspection device and a terminal of a semiconductor element during a semiconductor inspection process, and more specifically, to an elastic contactor that includes a hard head tip and a conductive soft body silicone, and in which a bonding bar formed in the body silicone is inserted into a bonding hole formed in the head tip, thereby suppressing separation of the head tip and the body silicone and reinforcing the bonding force even when repeated buffering actions are performed.

### CROSS-REFERENCE TO RELATED APPLICATION(S)

This application claims priority to Korean Patent Application No. 10-2024-0016403 filed in the Korean Intellectual Property Office on Feb. 2, 2024, the disclosure of which is incorporated by reference herein in its entirety.

### TECHNICAL FIELD

The present disclosure relates to a contactor that comes into contact with a test inspection device and a terminal of a semiconductor element during a semiconductor inspection process, and more specifically, to an elastic contactor that includes a hard head tip and a conductive soft body silicone, and in which a bonding bar formed in the body silicone is inserted into a bonding hole formed in the head tip, thereby suppressing separation of the head tip and the body silicone and reinforcing the bonding force even when repeated buffering actions are performed.

### DISCUSSION OF RELATED ART

Generally, semiconductors undergo semiconductor defect test after the manufacturing process to determine their electrical performance. Semiconductor defect test is performed by coupling a semiconductor test socket formed to be in electrical contact with the terminal of a semiconductor element to a board and combining the semiconductor to the semiconductor test socket.

A pin is a component included in a test socket used in a device for inspecting a circuit of a

semiconductor or electronic device or the like. One end of the pin is arranged to contact the lead terminal of a semiconductor or the like to be tested, and the other end is arranged to contact the circuit of the test device, and the input and output signals are analyzed as a test circuit.

With the development of semiconductor device integration technology and the trend toward miniaturization, the size and spacing of semiconductor device terminals, i.e., leads, are being miniaturized, and accordingly, a method is required to form a fine spacing between the conductive patterns of the test socket. Therefore, conventional pogo-pin type semiconductor test sockets have been limited in producing semiconductor test sockets for testing integrated semiconductor devices.

According to the structure of a conventional ultra-high current pogo pin disclosed in Korean Patent No. 10-2259074, a spring is embedded in a hollow outer cylinder, and an upper probe is supported on the upper end of the spring and a lower probe is supported on the lower end of the spring. The pogo pin is manufactured by machining and assembling three to four parts.

In conventional pogo pins, a mechanical gap must be formed to buffer the up and down motion of the spring, and when the gap is insufficient (narrow), the load applied to the probe or spring increases, thereby causing damage to the measured object, and when the gap is large, the contact resistance increases, thereby causing problems such as contact instability.

Further, in the field of testing contactors, which has been increasingly miniaturized in recent years, conventional pogo pins have small gaps and deviations due to machining tolerances caused by mechanical processing and assembly tolerances required for assembly, thereby causing instability of contact characteristics.

The movement of the pogo pins due to the gap causes instantaneous resistance and load instability even before the pogo pins themselves have reached the end of their service life, making accurate semiconductor testing difficult.

Therefore, it is necessary to develop a semiconductor testing contactor that can achieve miniaturization while maintaining stable load and contact resistance characteristics with structural stability and reduce costs.

### SUMMARY

In order to address the issues, an object of the present disclosure is to provide an elastic contactor with enhanced bonding that comes into contact with a test inspection device and a terminal of a semiconductor element during a semiconductor inspection process, and more specifically, to an elastic contactor that includes a hard head tip and a conductive soft body silicone, and in which a bonding bar formed in the body silicone is inserted into a bonding hole formed in the head tip, thereby suppressing separation of the head tip and the body silicone even when repeated buffering actions are performed.

Another object of the present disclosure is to provide an elastic contactor with enhanced bonding, in which a plurality of bonding bars formed in a silicone bonding part are each inserted into a plurality of bonding holes formed spaced apart from each other in the longitudinal direction of a connecting part of a head tip, thereby suppressing separation of the head tip and body silicone and maintaining adhesion, while at the same time preventing the buffer part from bending due to the connecting part, having a skeleton function to improve straightness and stably maintain the upper and lower positions without changing even with repeated buffering operations.

Still another object of the present disclosure is to provide an elastic contactor with enhanced bonding, in which the connecting part of the head tip is composed of a convex part and a concave part with different widths, thereby forming a step in the buffering direction, so that the silicone bonding part of the body silicone forms a hooking structure at the connecting part of the head tip to prevent separation even with long-term repeated use and increase durability.

Yet another object of the present disclosure is to provide an elastic contactor with enhanced bonding, in which a flat bonding plane is formed on one side of the connecting part, thereby securing a wider space for filling the silicon conductive material, so that large and numerous conductive particles can be placed there, thereby drastically reducing the contact resistance.

Still another object of the present disclosure is to provide an elastic contactor with enhanced bonding, in which the width of the probe part is formed smaller than that of the barrel supporting part, and the width of the contact part in the buffer part is formed smaller than that of the body part to form a hooking structure, thereby preventing the contactor from being detached when inserted into the test housing.

Yet another object of the present disclosure is to provide an elastic contactor with enhanced bonding, in which unlike conventional pogo pins that are assembled and manufactured, this product is manufactured by molding as a single structure, which saves cost and time due to the omission of the assembly process, and can stably maintain load and contact resistance characteristics even during repeated buffering without forming a mechanical gap.

To achieve the purpose, the present disclosure provides an elastic contactor with enhanced bonding, the contactor comprising a head tip 100 formed of a hard metal material and a body silicone 200 formed of a soft conductive material, wherein the head tip 100 includes a probe 110 in a upper part that contacts a terminal, a barrel supporting part 120 formed integrally with the probe 110 at a lower part of the probe 110 in a middle, and a connecting part 130 protruding below the barrel supporting part 120 at a lower part and having at least bonding hole 134 formed therein, and wherein the body silicone 200 includes a silicone bonding part 210 in which an insertion groove 211 is formed to receive the connecting part 130, a bonding bar 214 formed integrally with the silicone bonding part 210 and inserted into the bonding hole 134, and a body part 231 positioned below the silicone bonding part 210.

Further, the bonding holes 134 and bonding bars 214 are provided in multiple numbers and are spaced apart from each other in an upper and lower directions of the connecting part 130 and the insertion groove 211.

Further, the bonding hole 134 is formed so that its vertical length is longer than its horizontal width.

Further, the connecting part 130 includes a convex part 133 formed with a width smaller than that of the barrel supporting part 120; and a concave part 132 formed with a width smaller than that of the convex part 133 and arranged alternately with the convex part 133 to form a concavo-convex structure with the convex part 133.

Further, the connecting part 130 is formed in a cylindrical shape protruding downward from the barrel supporting part 120 and formed with flat bonding plane 131 on one side.

Further, the contactor further comprises a contact part 232 arranged at a lower part of the body part 231 and in contact with the terminal, a width of the body part 231 is formed to be larger than a width of the contact part 232 to form a step, and a width of the barrel supporting part 120 is the same as a width of the silicone bonding part 210.

Further, a length of the silicone bonding part 210 coupled with the connecting part 130 is shorter than a length of the body part 231.

The present disclosure has an effect in which the contactor comes into contact with a test inspection device and a terminal of a semiconductor element during a semiconductor inspection process, and more specifically, to an elastic contactor that includes a hard head tip and a conductive soft body silicone, and in which a bonding bar formed in the body silicone is inserted into a bonding hole formed in the head tip, thereby suppressing peeling of the head tip and the body silicone and enhancing the bonding strength even when repeated buffering actions are performed.

Further, the present disclosure has an effect in which a plurality of bonding bars formed in a silicone bonding part are each inserted into a plurality of bonding holes formed spaced apart from each other in the longitudinal direction of a connecting part of a head tip, thereby suppressing separation of the head tip and body silicone and maintaining adhesion, while at the same time preventing the buffer part from bending due to the connecting part, having a skeleton function to improve straightness and stably maintain the upper and lower positions without changing even with repeated buffering operations.

Further, the present disclosure has an effect, in which the connecting part of the head tip is composed of a convex part and a concave part with different widths, thereby forming a step in the buffering direction, so that the silicone bonding part of the body silicone forms a hooking structure at the connecting part of the head tip to prevent separation even with long-term repeated use and increase durability.

Further, the present disclosure has an effect, in which a flat bonding plane is formed on one side of the connecting part, thereby securing a wider space for filling the silicon conductive material, so that large and numerous conductive particles can be placed there, thereby drastically reducing the contact resistance.

Further, the present disclosure has an effect, in which the width of the probe part is formed smaller than that of the barrel supporting part, and the width of the contact part in the buffer part is formed smaller than that of the body part to form a hooking structure, thereby preventing the contactor from being detached when inserted into the test housing.

Further, the present disclosure has an effect, in which unlike conventional pogo pins that are assembled and manufactured, this product is manufactured by molding as a single structure, which saves cost and time due to the omission of the assembly process, and can stably maintain load and contact resistance characteristics even during repeated buffering without forming a mechanical gap.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a perspective view showing an elastic contactor with enhanced bonding according to an embodiment of the present disclosure;

FIG. 2 is an exploded perspective view of FIG. 1;

FIG. 3 is a cross-sectional view of FIG. 1, (a) is a longitudinal cross-sectional perspective view, and (b) is a partial cross-sectional perspective view;

FIG. 4 is a cross-sectional view showing a bonding hole of another embodiment of an elastic contactor with enhanced bonding of the present disclosure, (a) is one side view, and (b) is the other side view;

FIG. 5 is a perspective view showing a connecting part of another embodiment of an elastic contactor with reinforced bonding force of the present disclosure; and

FIG. 6 is a cross-sectional view of FIG. 5, (a) is a longitudinal cross-sectional perspective view, and (b) is a partial cross-sectional perspective view.

### DETAILED DESCRIPTION OF EXEMPLARY EMBODIMENTS

Hereinafter, a preferred embodiment of the present disclosure is described with reference to the accompanying drawings so that those skilled in the art can easily implement it.

The elastic contactor with enhanced bonding according to the present disclosure is a contactor used in a semiconductor testing process, which improves the structure of a conventional pogo pin to replace a spring and employs a conductive silicone material, but has reinforced bonding force to suppress the separation phenomenon between a head tip 100 made of a hard material and a body silicone 200 made of a soft material, the contactor comprising a head tip 100 formed of a hard metal material and a body silicone 200 formed of a soft conductive material, wherein the head tip 100 includes a probe 110 in a upper part that contacts a terminal, a barrel supporting part 120 formed integrally with the probe 110 at a lower part of the probe in a middle, and a connecting part 130 protruding below the barrel supporting part 120 at a lower part and having at least bonding hole 134 formed therein, and wherein the body silicone 200 includes a silicone bonding part 210 in which an insertion groove 211 is formed to receive the connecting part 130, a bonding bar 214 formed integrally with the silicone bonding part 210 and inserted into the bonding hole 134, and a body part 231 positioned below the silicone bonding part 210.

Once the semiconductor has been fabricated, a testing process is performed to ensure that each device on the semiconductor is functioning properly. The testing process sends and receives test signals to each semiconductor device to be tested and analyzes the electrical signals to determine whether the semiconductor device is operating normally.

To perform such a testing process, a testing device is provided that generates an electrical signal to be delivered to a semiconductor device, and the electrical signal of the testing device is delivered through a contactor in contact with the testing device, and the semiconductor device receives the electrical signal of the testing device in contact with the contactor and returns the electrical signal to the testing device.

The contactor of the present disclosure is a pin inserted into a test housing (not shown) of a test socket (not shown), which exists in an upright state supported by the test housing, and is elastically supported by a pressing force that brings the test device and the semiconductor device closer to each other, thereby improving the contact efficiency between the test device and the semiconductor device, and cushioning to minimize damage caused by pressing.

Conventional pogo pins are manufactured by assembling a spring for buffering, a barrel to house the spring, and an upper and lower plunger at the top and bottom of the spring. However, the conventional pogo pin structure is very difficult to manufacture below a certain size due to the elastic force of the spring and the thickness of the barrel, making it unsuitable for the testing process of miniaturized semiconductor devices.

Thus, the present disclosure comprises a single structure that can be molded and manufactured as a whole to facilitate easy fabrication in small sizes suitable for testing processes of micronized semiconductor devices. Specifically, the contactor comprises a head tip 100 in contact with a terminal on the upper end and a body silicon 200 in contact with a terminal on the lower end, and is bonded by inserting a bonding bar 214 formed in the body silicon 200 through a bonding hole 134 formed in the head tip 100.

The head tip 100 is formed of a hard conductive material and the body silicone 200 is formed of a soft conductive material. The head tip 100 and body silicone 200, which are different materials, are molded as a single piece by being joined together by the bonding hole 134 and the bonding bar 214.

When the contactor is subjected to pressing forces in the upward and downward directions during the testing process of the present disclosure, the body silicone 200 of the soft material acts as an elastic buffer to minimize damage to the terminals.

Since a primer for silicone adhesion is mixed during the molding process of the body silicone 200, the contact portion 232 of the head tip 100 and the top of the body silicone 200 are strongly contacted, Furthermore, the bonding bar 214 of the body silicone 200 is inserted into the bonding hole 134 of the head tip 100. Thus, the separation of the head tip 100 and the body silicone 200 is suppressed even when the contactor is buffered in the up and down directions, and a very strong bonding force is maintained, and the contact resistance remains low even in long-term use.

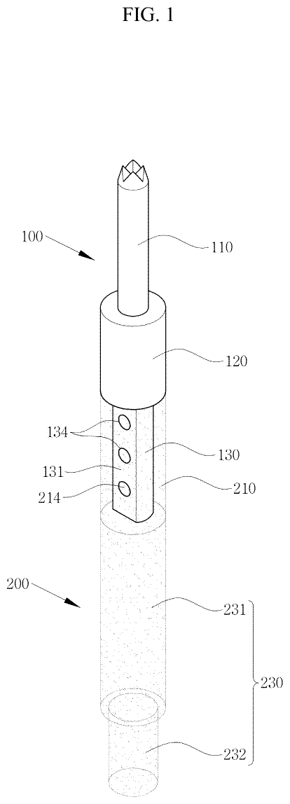

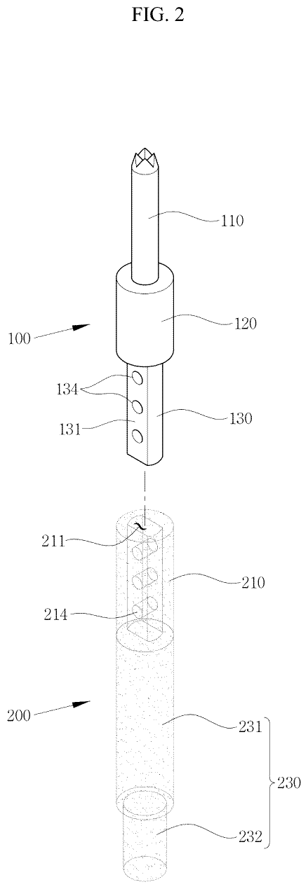

FIG. 1 is a perspective view illustrating a contactor according to one embodiment of the present disclosure, and FIG. 2 is an exploded perspective view of FIG. 1. Referring to FIGS. 1 and 2, a contactor according to one embodiment of the present disclosure is a contactor that fits into a test housing of a test socket and contacts terminals of a test device and a semiconductor device to electrically interconnect and communicate electrical signals. In this case, the test device and the semiconductor device are placed on the upper and lower sides of the contactor, respectively, but the upper and lower positions of the arrangement may be reversed.

The contactor of the present disclosure is formed by the bonding of a head tip 100 formed of a hard material and thus highly conductive, and a body silicone 200 formed of a soft material and thus highly resilient and conductive by mixing conductive powders.

The top of the head tip 100 contacts a terminal located at the top of the contactor, and the bottom of the body silicon 200 contacts a terminal located at the bottom of the contactor. To improve the contact between the test device, the contactor, and the semiconductor device, the contactor is pressed in a direction that brings the test device and the semiconductor device closer together, and the contactor is elastically buffered to prevent damage to the terminals.

To this end, the body silicone 200 is made of silicone material having elasticity as one embodiment, and conductive powder (particles) are mixed into the silicone to transmit electrical signals. And the head tip 100 is formed from a metallic material, such as BeCu, SUS, SK4, PD Alloy, or the like, having hard and conductive properties. Therefore, the head tip 100 and the body silicon 200 have conductive properties, so that the test device and the semiconductor device may be electrically connected and the testing process may be performed.

The head tip 100 is formed with a probe 110 having a pointed top to contact a terminal (a test device or a terminal of a semiconductor device) located on the upper part of the contactor. A lower part of the probe 110 is provided with a barrel supporting part 120 with a greater width than the probe 110. The probe portion 110 and the barrel supporting part 120 may be integrally formed, but may be formed at different widths. The lower part of the barrel supporting part 120 is provided with a connecting part 130, which is a coupling portion with the body silicone 200. That is, the head tip 100 is integrally formed from top to bottom with the probe 110, the barrel supporting part 120, and the connecting part 130. The ‘width’ is the horizontal length of the cross-section, which can be the diameter if the cross-section is circular or the length of the side if the cross-section is square.

In the head tip 100, the barrel supporting part 120 is formed with the greatest width relative to the probe 110 and the connecting part 130, and the connecting part 130 is formed with a smaller width than the barrel supporting part 120.

The body silicone 200 is provided with a silicone bonding part 210, which is a part for binding with the connecting part 130 of the head tip 100 and a buffer part 230, which is a part for buffering an external force applied to the contactor, at a lower part of the silicone bonding part 210. More specifically, the buffer part 230 comprises a body part 231 forming a body, and a contact part 232 disposed at a lower part of the body part 231, formed in a size smaller than the width of the body part 231, and contacting a terminal (terminal of a test device or semiconductor device) at the lower part of the contactor. In other words, the body silicone 200 is formed as an integration of the silicone bonding part 210, the body part 231 of the buffer part 230, and the contact part 232 of the buffer part 230 from the top to the bottom.

The body part 231 and the contact part 232 are elastomers that contract upon pressurization and expand upon release of the pressurization, and the length of the silicone bonding part 210 is formed to be shorter than the length of the body part 231.

The silicone bonding part 210, the body part 231, and the buffer part 230 may be molded from silicone mixed with a conductive powder so that they have the same elasticity and conductivity, or they may be molded to have different elasticity and conductivity.

The width of the probe 110 is formed in a size smaller than the width of the barrel supporting part 120, and the barrel supporting part 210 of the body silicone 200 and the body part 231 of the buffer part 230 may be formed with the same width as the barrel supporting part 120.

As a structure for binding the head tip 100 and the body silicone 200, a connecting part 130 is formed on the head tip 100 and a silicone bonding part 210 is formed on the body silicone 200. In the manufacturing and molding of the body silicone 200, before it is cured, a conductive powder is mixed for transmission of electrical signals, and a primer for bonding silicone is further mixed for bonding with the head tip 100. After molding and manufacturing, the silicone bonding part 210 is strongly bonded to the lower surface of the barrel supporting part” 120 and the outer surface of the connecting part 130 to form an integral structure. Referring to the structure of the connecting 130 and the silicone bonding part 210

in detail, the connecting 130 is formed with a smaller width than the barrel supporting part 120 and is protruding downwardly, and the silicone bonding part 210 is formed with an insertion groove 211 into which the connecting 130 is inserted.

And in the connecting part 130, a bonding hole 134 is formed, which is a hole that penetrates the connecting part 130 in a horizontal direction, and in the insertion groove 211 of the silicone bonding part 210, a bonding bar 214 is formed, which is a bar that passes through the bonding hole 134, in which the bonding bar 214 crosses the insertion groove 211 in a horizontal direction. In this case, the horizontal direction refers to a direction orthogonal to the longitudinal direction of the longitudinally disposed contactor. In the area where the connecting part 130 and the silicone bonding part 210 are coupled, the silicone bonding part 210 is filled with a conductive powder mixture, except for the volume occupied by the connecting part 130 and the bonding hole 134. Thus, the bonding bar 214 is also a conductive material to transmit electrical signals upon contact with the connecting part 130.

When the head tip 100 and body silicone 200 are bonded by relying on a primer for silicone bonding, there is a problem that the head tip 100 and body silicone 200 are separated at the bonding site by repeated buffering of the contactor for a long period of time. The present disclosure forms a bonding hole 134 in the connecting part 130 to prevent the head tip 100 and the body silicone 200 from being detached, and a bonding bar 214 formed integrally with the silicone bonding part 210 is inserted horizontally into the bonding hole 134, so that the contactor of the present disclosure can maintain a stable contact resistance without separating the head tip 100 and the body silicone 200 even when the contactor is subjected to repeated cushioning.

The body silicone 200 of the present disclosure is made integrally with the head tip 100 by filling the silicone mixed with conductive powder into a mold that guides the shape of the body silicone 200 before it is cured. Thus, the silicone bonding part 210 and the bonding bar 214 are of the same material and are formed integrally.

The connecting part 130 is formed in a cylindrical shape protruding downwardly from the barrel supporting part 120, and is formed with a bonding plane 131 having a flat shape on one side. The bonding plane 131 may be formed on one or more on the outer faces of the connecting part 130. Since the silicone bonding part 210 manufactured by the method is filled and molded without any empty space between the connecting parts 130, a flat shape matching the bonding plane 131 of the connecting part 130 can be molded on one side of the insertion groove 211. The bonding plane 131 of the connecting part 130 and the hooking structure of the insertion groove 211 prevent the silicone bonding part 210 from rotating circumferentially of the connecting part 130.

Furthermore, the space in which the silicone bonding part 210 is filled is further expanded at the site where the connecting part 130 and the silicone bonding part 210 are bonded. In other words, a larger amount of silicone mixed with conductive powder can be filled than with a connecting part 130 having a cylindrical shape that is made up of arcs and straight lines (faces by the bonding plane 131) when the outer surface of the connecting part 130 is viewed in cross-section, and is not shaved by the bonding plane 131, so that a larger amount of conductive powder can be filled, resulting in a lower contact resistance.

Further, at the connecting part 130 and the silicone bonding part 210, which is the area where the head tip 100 and the body silicone 200 are overlapped, the connection portion 130 of a hard material supports the silicone bonding part 210. This allows the connecting part 130 to function as a skeleton to support the body silicone 200, thereby ensuring that the contactor of the present disclosure inserted into the test housing of the test socket is not bent (buckling) under cushioning and improves its straightness. This allows the probe 110 and contact part 232 to contact the upper and lower terminals in their original positions without deviating from their original positions, thereby improving contact precision.

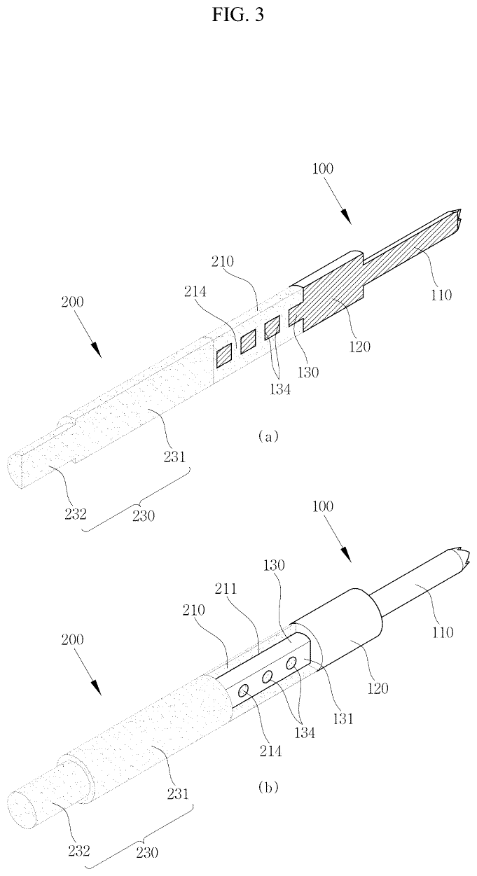

FIG. 3 is a cross-sectional view illustrating the connecting part 130 and the silicone bonding part 210. Referring to FIG. 3, the bonding holes 134 are provided in plurality and may be spaced apart from each other along the longitudinal direction of the connecting part 130. The longitudinal direction refers to the direction from the probe 110 of the contactor to the contact part 232. The bonding bars 214 are also arranged spaced apart from each other along the longitudinal direction of the insertion groove 211 in accordance with the number of bonding holes 134.

In a plurality of bonding hole 134-bonding bar 214 configurations, the bonding hole 134-bonding bar 214 configuration closest to the barrel supporting part 120 are intended to prevent separation of the silicone bonding part 210 where the silicone bonding part 210 face-contacts the underside of the barrel supporting part 120. This maintains good contact between the head tip 100 and the body silicone 200 and prevents contact resistance from increasing.

Further, the bonding hole 134-bonding bar 214 configuration farthest from the barrel supporting part 120 is intended to improve the straightness of the soft body silicone 200. Since the skeletonized connecting part 130 protrudes downward and supports the body silicon 200, the bending or buckling phenomenon of the body silicon 200 is suppressed as much as possible to prevent the position of the probe 110 and the contact part 232 from deviating from the terminal.

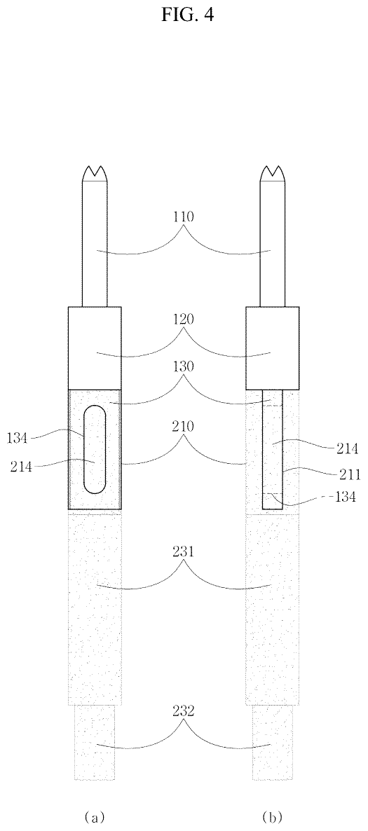

FIG. 4 is a view illustrating the bonding hole 134 of a contactor according to another embodiment of the present disclosure. Referring to FIG. 4, the connecting part 130 is formed with a bonding hole 134 into which the bonding bar 214 of the silicone bonding part 210 is inserted, and the bonding hole 134 is elongated along the longitudinal direction of the connecting part 130 so that the length is longer in the up and down directions than the width in the horizontal direction. The bonding hole 134 shown in FIG. 4 illustrates a different embodiment from the bonding hole 134 shown in FIGS. 1, 2, and 3, and the structure of the head tip 100 and the body silicone 200 is the same except for the bonding hole 134. The bonding hole 134, which is longer than it is wide, may be provided in a single bonding hole as shown in FIG. 4, or two or more bonding holes 134 longer than the width can be formed spaced apart from each other in a configuration not shown.

When the bonding holes 134 are formed with a longer length than width, the bonding bars 214 are correspondingly formed with a longer length than width to fill the bonding holes 134. Thus, the long-hole shape of the bonding hole 134 filled with the bonding bar 214 prevents the silicone bonding part 210 from being detached from the underside of the barrel supporting part 120, and can improve contact resistance characteristics by providing more area for filling silicone mixed with conductive powder at the site where the connecting part 130 and the silicone bonding part 210 are bonded.

In embodiments where the bonding hole 134 is formed with a length greater than a width, the connecting part 130 may be formed with a bonding plane 131 that is a flat surface.

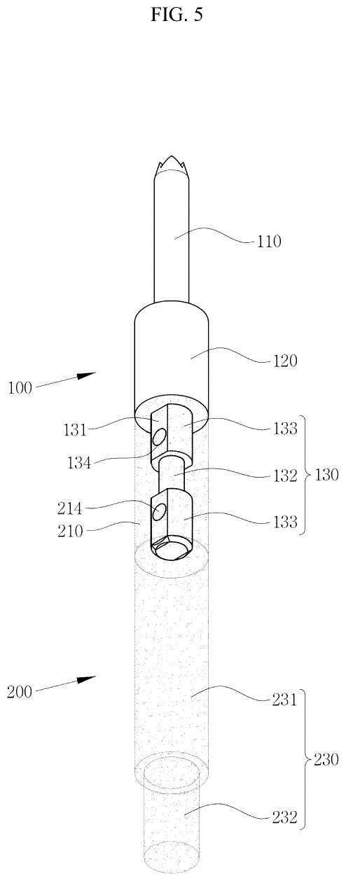

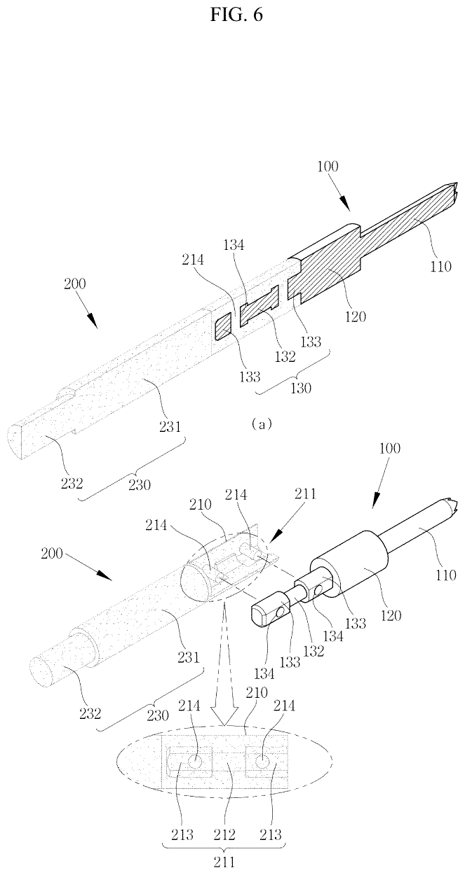

FIG. 5 is a perspective view illustrating connecting part 130 according to another embodiment of the present disclosure, and FIG. 6 is a cross-sectional view of FIG. 5. Referring to FIGS. 5 and 6, in a contactor according to another embodiment of the present disclosure, a head tip 100 formed of a hard conductive material and a body silicone 200 formed of a soft silicone material mixed with a conductive powder are interconnected.

The head tip 100 is provided with a probe 110 disposed on the upper part and in contact with a terminal on the upper part of the contactor, and a barrel supporting part 120 is provided on the lower part of the probe 110. A connecting part 130 for bonding with the body silicon 200 is formed in a concave-convex shape on the lower part of the barrel supporting part 120.

The body silicone 200 is provided with a silicone bonding part 210 for bonding with the concave-convex shaped connecting part 130, and a buffer part 230 for buffering at the lower part of the silicone bonding part 210, wherein the buffer part 230 is provided with a body part 231 forming a body and a contact part 232 disposed at the lower part of the body part 231 for contacting a terminal of the lower part of the contactor.

The connecting part 130 for bonding with the body silicon 200 includes a convex part 133 formed with a width smaller than that of the barrel supporting part 120 and a concave part 132 formed with a width smaller than that of the convex part 133 and arranged alternately with the convex part 133 to form a concavo-convex structure with the convex part 133.

The concave part 132 and the convex part 133 may be provided with one or more of each, and one embodiment of the present disclosure includes show two convex parts 133 and one concave part 132 between two the convex parts 133. However, it is not limited to this, and it is preferred that a plurality of the concave parts 132 and the convex parts 133 are arranged alternately each other to form a concavo-convex structure with different widths, and that the convex part 133 having a greater width than the concave part 132 is arranged last at the lower end of the connecting part 130.

The connecting part 130 is formed in a concavo-convex structure by the arrangement of the concave part 132 and the convex part 133, the insertion groove 211 into which the connecting part 130 is inserted is also formed in a concavo-convex structure. More specifically, the insertion groove 211 comprises a convex groove 213 receiving the convex part 133; and a concave groove 212 receiving the concave part 132. In a preferred embodiment, the rear end of the connecting part 130 has a larger width convex part 133 than the concave part 132, so that the concave groove 212 engages the convex part 133 at the rear end of the connecting part 130 to inhibit separation of the body silicone 200 downwardly from the head tip 100.

In addition, a bonding hole 134 is formed in the convex part 133, which is formed with a larger width than the concave part 132, and a bonding bar 214 formed to horizontally cross the insertion groove 211 of the silicone bonding part 210 is inserted into the bonding hole 134 to bind the connecting part 130 and the silicone bonding part 210. Therefore, for the molding manufacture of the body silicone 200, a silicone adhesive primer is mixed, and it is bonded to the barrel supporting part 120 and the outer surface of the connection part 130. The silicone bonding part 210 is bonded to the connecting part 130 by stepped embedding in the concavo-convex structure formed by the concave part 132 and the convex part 133, and the bonding force can be further strengthened by inserting the bonding bar 214 of the silicone bonding part 210 into the bonding hole 134 formed in the convex part 133.

In the drawing, the bonding holes 134 are formed in the convex parts 133 and the bonding bars 214 are formed in the silicone bonding part 210 as many as the number of convex parts 133, but the bonding holes 134 may also be formed in the concave part 132 and the bonding bars 214 inserted into the bonding holes 134 formed in the concave part 132 may be further formed.

Since the convex part 133 is formed with a larger width than the concave part 132, a flat surface, the bonding surface 131, is formed on the convex part 133. The bonding plane 131 prevents the silicone bonding part 210 from rotating circumferentially of the connecting part 130 and allows more filling space for the silicone mixed with conductive powder, thereby reducing contact resistance. Although not shown, a further bonding plane 131 may also be formed on the concave portion 132.

In other contactor of the present disclosure, the width of the probe 110 is formed to be smaller than the width of the barrel supporting part 120 so that the upper part of the contactor is stepped. Also, the width of the body part 231 in the buffer part 230 is formed to be larger than the width of the contact part 232, so that the lower part of the contactor is stepped. The step difference caused by the difference in width of the probe 110 and the barrel supporting part 120 and the difference in width of the body part 231 and the contact part 232 prevents the detachment of the contactor of the present disclosure when inserted into the test housing.

What is claimed is:

1. An elastic contactor with enhanced bonding, the contactor comprising a head tip formed of a hard metal material and a body silicone formed of a soft conductive material,
wherein the head tip includes a probe in an upper part that contacts a terminal, a barrel supporting part formed integrally with the probe at a lower part of the probe in a middle, and a connecting part protruding below the barrel supporting part at a lower part and having at least bonding hole formed therein, and
wherein the body silicone includes a silicone bonding part in which an insertion groove is formed to receive the connecting part, a bonding bar formed integrally with the silicone bonding part and inserted into the bonding hole, and a body part positioned below the silicone bonding part.

2. The elastic contactor of claim 1,
wherein the bonding holes and bonding bars are provided in multiple numbers and are spaced apart from each other in an upper and lower directions of the connecting part and the insertion groove.

3. The elastic contactor of claim 1,
wherein the bonding hole is formed so that its vertical length is longer than its horizontal width.

4. The elastic contactor of claim 1,
wherein the connecting part includes a convex part formed with a width smaller than that of the barrel supporting part; and a concave part formed with a width smaller than that of the convex part and arranged alternately with the convex part to form a concavo-convex structure with the convex part; and
wherein the insertion groove includes a convex groove receiving the convex part; and a concave groove receiving the concave part and forming a hooking structure with the convex part.

5. The elastic contactor of claim 1,
wherein the connecting part is formed in a cylindrical shape protruding downward from the shaft supporting part and formed with flat bonding plane on one side.

6. The elastic contactor of claim 1, further comprising a contact part arranged at a lower part of the body part and in contact with the terminal,
wherein a width of the body part is formed to be larger than a width of the contact part to form a step, and
wherein a width of the barrel supporting part is the same as a width of the silicone bonding part.

7. The elastic contactor of claim 1,
wherein a length of the silicone bonding part coupled with the connecting part is shorter than a length of the body part.
